(19) United States
(12) Patent Application Publication
(10) Pub. No.: US 2011/0262807 A1
(43) Pub. Date: Oct. 27, 2011

(54) Carbon Nanotube Augmented Sulfur Cathode for an Elemental Sulfur Battery

(76) Inventors: Arthur Douglas Boren, San Jose, CA (US); Darin Scott Olson, Newark, CA (US)

(21) Appl. No.: 13/092,274

(22) Filed: Apr. 22, 2011

Related U.S. Application Data
(60) Provisional application No. 61/342,889, filed on Apr. 22, 2010.

(51) Int. Cl. H01M 4/64; H01M 4/04; B05D 5/12; C23C 16/50; B82Y 40/00; B82Y 30/00

(52) U.S. Cl. 429/211; 427/122; 977/742; 977/842

(57) ABSTRACT

An electrode for a battery is augmented with vertically aligned carbon nanotubes, allowing both improved storage density of lithium ions and the increase electrical and thermal conductivity. Carbon nanotubes are extremely good electrical and thermal conductors, and can be grown directly on the electrode (e.g., anode or cathode) current collector metals, allowing direct electrical contact. Additionally carbon nanotubes have an ideal aspect ratio, having lengths potentially thousands of times as long as their widths, 10 to 1,000 nanometers. In an embodiment, the carbon nanotube electrode (e.g., a cathode) comprises embedded elemental sulfur, allowing both the improved retention of elemental sulfur and increase electrical conductivity. The surface of carbon nanotubes are nearly chemically identical to carbon, binding the sulfur atoms to the carbon nanotubes, preventing the “loss” of sulfur with the formation of LiS intermediate products.

This application claims priority from U.S. provisional patent application Ser. No. 61/342,889, filed on Apr. 22, 2010, entitled “Carbon Nanotube Augmented Sulfur Cathode for an Elemental Sulfur Battery”; which is incorporated herein by reference.

### BACKGROUND

Current lithium battery technology is either lithium ion based, or lithium metal based, in either case the system does not use elemental sulfur in the cathode.

Elemental sulfur is difficult to be incorporated in the cathode of a battery. One of the reasons is that many of the intermediate lithium/sulfur reaction products are mobile, or soluble, in most materials chosen for the electrolyte. If the lithium/sulfur intermediate product leaves the region of the cathode further lithium reactions with the sulfur stop and no current will flow. Thus the sulfur is “lost” to the battery, although still physically present in the battery housing. Another reason is that sulfur is not a good conductor of electrons, having a resistance of 2×10¹⁵ Ω·m, thus elemental sulfur as a battery cathode increases the internal resistance of the battery, limiting battery performance. To combat these issues many elemental lithium batteries use an iron-sulfur alloy, with additional carbon. The alloying of the sulfur to iron avoids the soluble intermediate products, preventing the loss of sulfur, and the carbon powder decreases the internal electrical resistance of the battery. Both the iron, used to form and alloy, and the carbon, used to decrease the resistance, add weight to the battery system, but don't add energy, resulting in a decrease in the energy density of the final battery.

With a standard polymer electrolyte, up to 80% of the sulfur can be lost in as little as ten cycles. This problem has been partially solved by using meso-porous carbon particles to bind the sulfur to the cathode area. Such a battery has shown significant improvement in decreasing the amount of sulfur lost per cycle, but remains an incomplete solution, losing 25% of the sulfur in 10 charge-discharge cycles. This battery also showed greater than ideal internal resistance as the meso-porous carbon particles were not in direct electrical contact with the cathode electrode and current needs to pass from carbon particle to particle before reaching the electrode.

### SUMMARY

The present invention discloses electrodes for batteries, and batteries utilizing the electrodes, wherein the electrode comprises carbon nanotubes (CNT) chemically bonded to a collector plate.

In an embodiment, the present electrode is augmented with vertically aligned carbon nanotubes, allowing both the improved storage density, for example of lithium ions, over existing lithium salts, and the increase electrical and thermal conductivity. CNTs are extremely good electrical and thermal conductors, and can be grown directly on the electrode (e.g., anode or cathode) current collector metals, allowing direct electrical contact.

In an embodiment, the present CNT electrode (e.g., a cathode) comprises elemental sulfur, allowing both the improved retention of elemental sulfur and increase electrical conductivity. Additionally CNTs have an ideal aspect ratio, having lengths potentially thousands of times as long as their widths, 10 to 1,000 nanometers, allowing an elemental sulfur cathode to be penetrated and crisscrossed with innumerable number of low resistance electron paths from the cathode lead. Also, the surface of CNTs are nearly chemically identical to carbon, binding the sulfur atoms to the CNTs preventing the “loss” of sulfur with the formation of LiS intermediate products.

### BRIEF DESCRIPTION OF THE DRAWINGS

FIG. 1 illustrates a schematic cross-sectional view of a CNT electrode according to an embodiment of the present invention.

FIG. 2 illustrates a schematic cross-sectional view of another CNT electrode according to an embodiment of the present invention.

FIG. 3 illustrates a schematic cross-sectional view of another CNT electrode according to an embodiment of the present invention.

FIG. 4 illustrates a CNT cathode according to an embodiment of the present invention.

FIG. 5 illustrates a schematic cross-sectional view of another CNT cathode according to an embodiment of the present invention.

FIG. 6 illustrates a schematic cross-sectional view of another CNT cathode according to an embodiment of the present invention.

FIG. 7 illustrates a battery according to an embodiment of the present invention.

FIG. 8 illustrates an exemplary flowchart of the sulfur embedded CNT cathode according to an embodiment of the present invention.

FIG. 9 illustrates an exemplary reel-to-reel system according to an embodiment of the present invention.

### DETAILED DESCRIPTION OF THE PREFERRED EMBODIMENTS

In an embodiment, the present invention discloses a vertically aligned carbon nanotube (CNT) augmented electrode, to be used as a base for a lithium ion anode or an elemental sulfur cathode, to improve the performance of a lithium ion battery, and allows the repeated discharging and recharging (cycling) of a lithium ion battery.

In an embodiment, the present invention discloses an electrode (such as an anode or a cathode) augmented with carbon nanotubes, allowing both the improved storage density of lithium ions, over existing lithium salts, and the increase electrical and thermal conductivity. Carbon nanotubes offer high strength-to-weight ratios and superior mechanical properties, in additional to excellent electrical conductivity. CNTs can be grown on the surface of a metal collector, to produce nanoscale composites to be used as electrodes in battery, magnetic storage, fuel cell, and composite applications. Carbon nanotubes or carbon nanofibers have excellent electric conductivity, together with large surface area accessible by the ions of the electrolyte, thus offering low resistance to be used as electrode materials for battery applications.

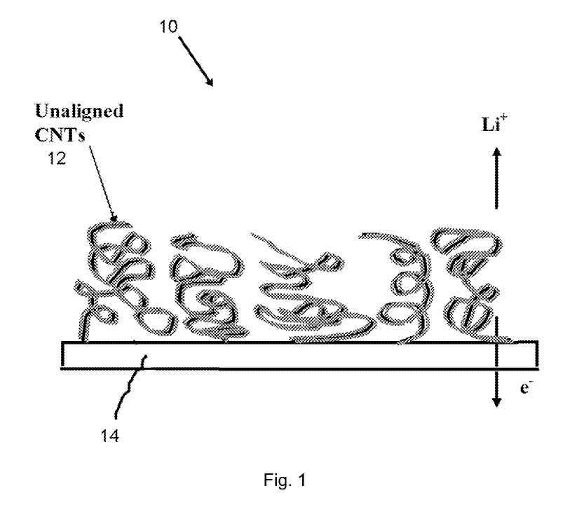

FIG. 1 illustrates a schematic cross-sectional view of a CNT electrode according to an embodiment of the present invention. The electrode 10 comprises CNTs 12 growing on a collector plate 14, thus CNTs are chemically bonded to the collector plate. The collector plate can comprise a seed layer for growing CNTs.

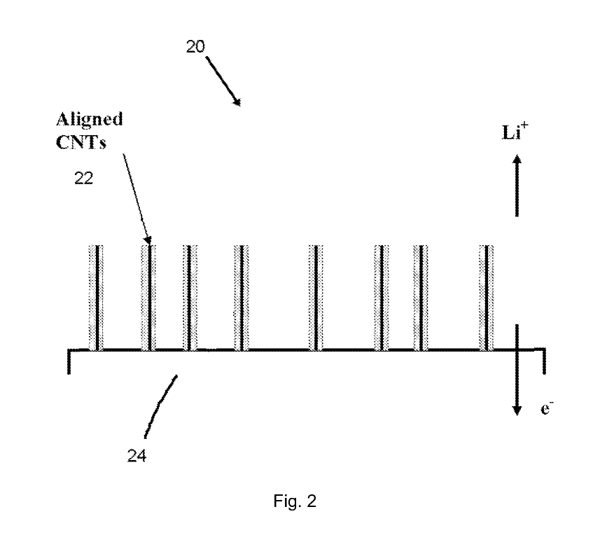

FIG. 2 illustrates a schematic cross-sectional view of another CNT electrode according to an embodiment of the present invention. The electrode 20 comprises vertically aligned CNTs 22 growing on a collector plate 24, thus CNTs are chemically bonded to the collector plate.

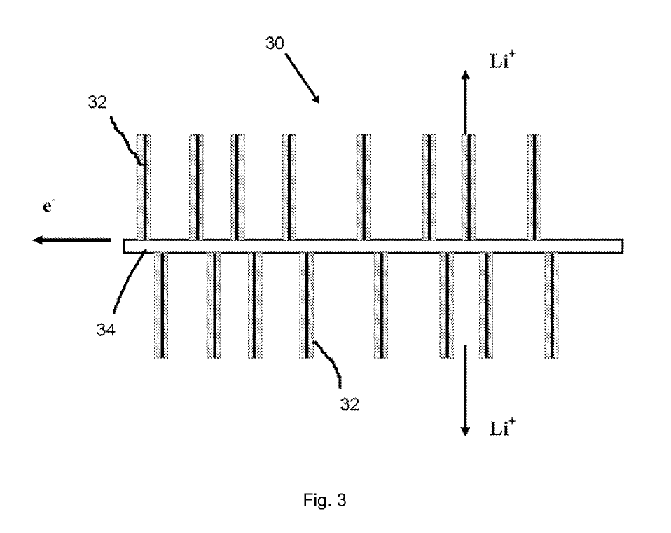

FIG. 3 illustrates a schematic cross-sectional view of another CNT electrode according to an embodiment of the present invention. The electrode 30 comprises vertically aligned CNTs 32 growing on both sides of a collector plate 34, thus CNTs are chemically bonded to the collector plate.

The carbon nanotubes include single-walled carbon nanotubes (SWNTs), multi-walled carbon nanotubes (MWNTs), which may be prepared by any conventional process such as arc-discharge, laser vaporization, chemical vapor deposition (CVD) and high pressure decomposition of carbon monoxide (HiPCO). In an embodiment, seed layer or catalyst components can be provided on the collector plate to facilitate the growing of CNTs.

In an embodiment, the present invention discloses a carbon nanotube (CNT) augmented sulfur cathode to improve the performance of elemental lithium sulfur (LiS) or lithium ion and sulfur battery, allowing the repeated discharging and recharging (cycling) of a lithium sulfur battery. The present elemental lithium sulfur battery could provide energy densities (power/pound) over four times those of batteries currently available.

In an embodiment, the present cathode augmented with carbon nanotubes can allow both the improved retention of elemental sulfur, over the meso-porous carbon case, and increase electrical conductivity. Carbon nanotubes are extremely good electrical conductors, and can be grown directly on cathode lead metals allowing direct electrical contact. Additionally CNTs have an ideal aspect ratio, having lengths potentially thousands of times as long as their widths, 10 to 1,000 nanometers, allowing an elemental sulfur cathode to be penetrated and crisscrossed with innumerable number of low resistance electron paths from the cathode lead. Additionally the surface of CNTs are nearly chemically identical to carbon, including meso-porous carbon, binding the sulfur atoms to the CNTs preventing the “loss” of sulfur with the formation of LiS intermediate products. In an embodiment, elemental sulfur is incorporated in the form of an active material comprising elemental sulfur.

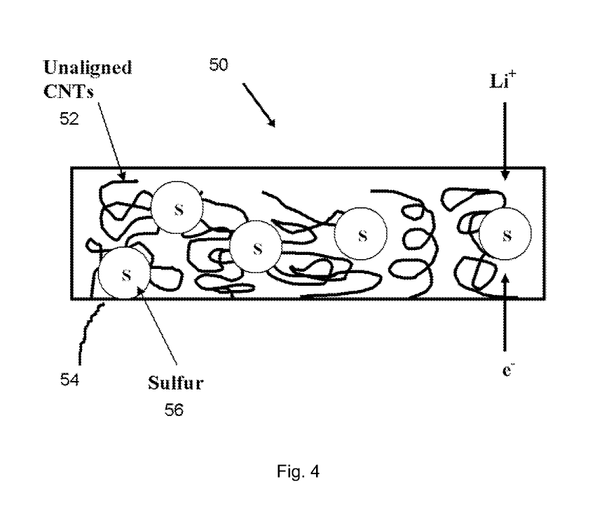

FIG. 4 illustrates a CNT cathode according to an embodiment of the present invention. A CNT augmented cathode 50 would consist of a “mat”, “forest”, or “mass” of carbon nanotubes 52 grown, or otherwise bonded, directly on the cathode lead metal 54. This mat of CNTs would function as both the electrical path for electrons to the reacting sulfur and the physical substrate to which the sulfur is bound. A preferred construction process is to first grow, or bond, the CNTs 52 to the cathode lead metal 54, then infuse the mat with elemental sulfur 56.

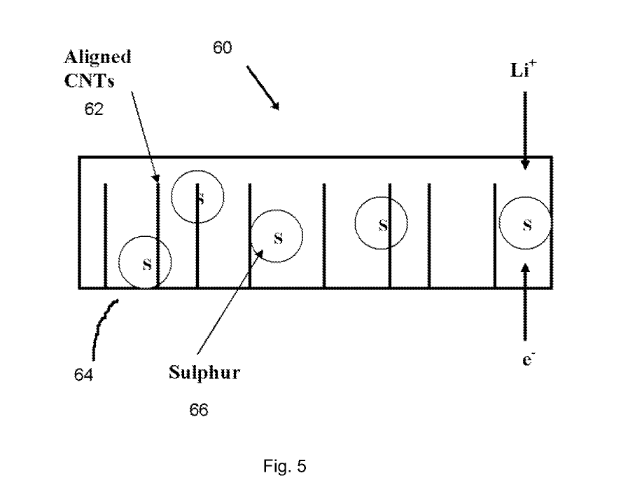

FIG. 5 illustrates a schematic cross-sectional view of another CNT cathode according to an embodiment of the present invention. The cathode 60 comprises vertically aligned CNTs 62 growing on a collector plate 64, thus CNTs are chemically bonded to the collector plate. Elemental sulfur 66 is infused to the CNTs, for example, by applying molten sulfur to the CNT surface.

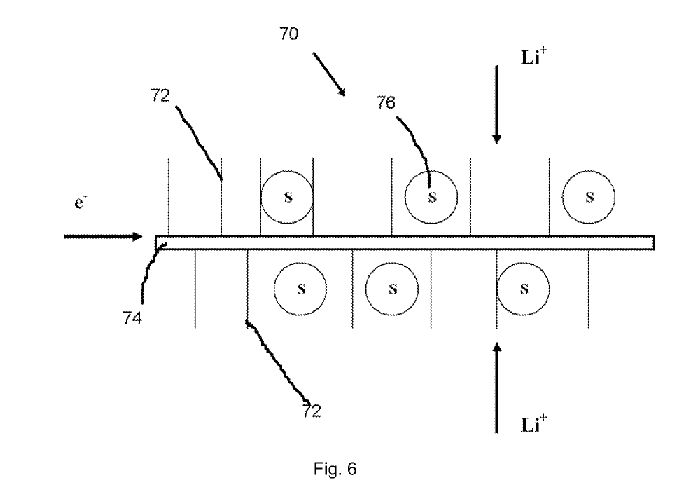

FIG. 6 illustrates a schematic cross-sectional view of another CNT cathode according to an embodiment of the present invention. The cathode 70 comprises vertically aligned CNTs 72 grown on both sides of a collector plate 74 with elemental sulfur 76 bonded to the CNTs.

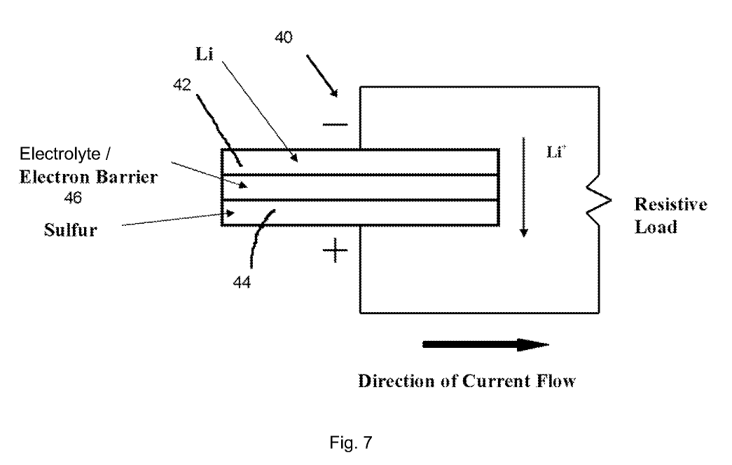

In an embodiment, the present invention discloses a battery employing a CNT cathode with embedded sulfur. FIG. 7 illustrates a battery according to an embodiment of the present invention. The battery system 40 includes an anode 42, a cathode 44, and a separator 46. In an embodiment, the anode 42 and cathode 44 comprise CNT materials, which can be any known nanostructured carbon material, and preferably vertically aligned CNTs. The CNT augmented cathode, impregnated with sulfur, would be placed in contact with an electrolyte, which in turn is in contact with the elemental lithium battery anode, or potentially a lithium ion anode. This construction allows lithium ions (Li⁺) to flow from the anode to the cathode, while the electrolyte prevents the flow of electrons. Once the flow of electrons is allowed, through an external circuit, the lithium reacts with the elemental sulfur, forming intermediate and final lithium-sulfur compounds. The more electrons flow through the external circuit the more the reaction continues until all of the available sulfur reacts with all of the available lithium and the battery is discharged. The battery is recharge the same way except that the charger drives the battery in reverse, causing the lithium ions to cross back through the electrolyte and combine with supplied electrons to become elemental lithium again. The CNTs are also capable of absorbing and desorbing lithium (or other components) in an electrochemical system, with lithium metal dispersed in the CNT of the anode.

The CNT augmented cathode for an elemental sulfur battery can be used wherever battery applications require high energy densities (power to weight ratio) or high energy potentials are desired. The anode can be a CNT anode, having embedded lithium or lithium ions.

In an embodiment, the carbon nanotubes are grown by PECVD process. The PECVD process can grow CNTs on one side, or on two sides simultaneously. A seed layer can be deposited first on a collector plate for facilitate the growth of CNTs. In an embodiment, after the formation of CNTs, sulfur can be applied to the CNTs, for example, by pouring molten sulfur on the CNTs. Optional barrier layer can be applied afterward before applying the opposite electrode.

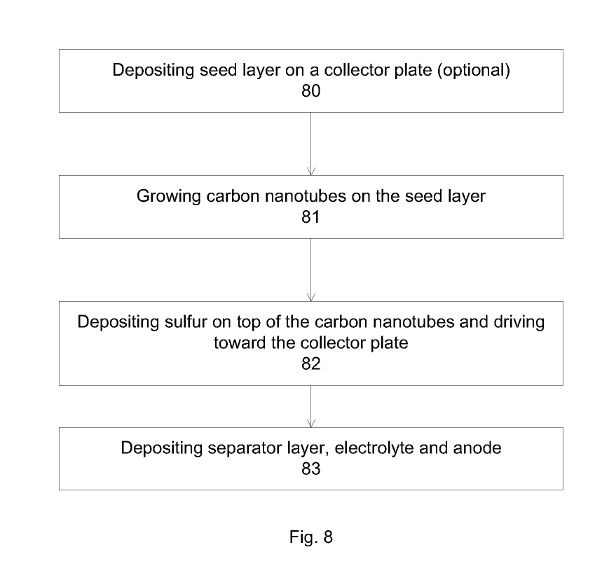

FIG. 8 illustrates an exemplary flowchart of the sulfur embedded CNT cathode according to an embodiment of the present invention. In operation 80, optional seed layer is deposited on a collector plate. In operation 81, CNTs are grown on the seed layer, for example, by a PECVD process. In operation 82, molten sulfur is applied on top of the CNTs, which can be driven to the CNTs. In operation 83, separation layer, electrolyte, and anode are applied to form a battery.

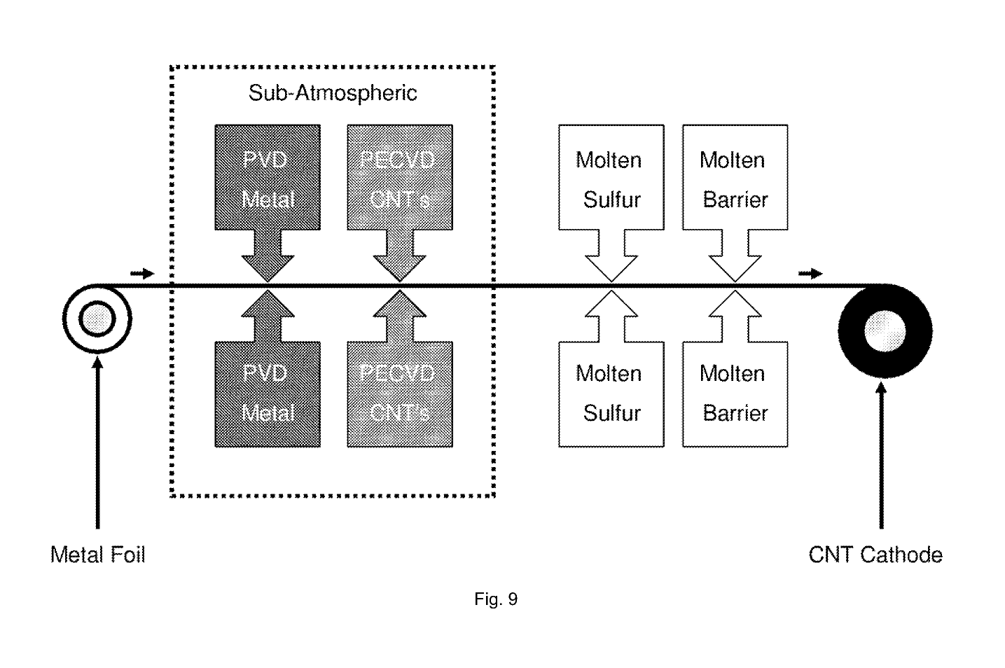

In an embodiment, a reel-to-reel process can be used for preparing the sulfur embedded CNT cathode. FIG. 9 illustrates an exemplary reel-to-reel system according to an embodiment of the present invention. A metal foil roll is running through multiple stations for sequential processing. In sub-atmospheric environment, a PVD system can deposit a seed metal layer and a PECVD system can grow carbon nanotubes on the seed metal layer. The carbon nanotubes are preferably vertically aligned to the metal seed layer. Afterward, the metal foil exits the sub-atmospheric environment, and enters a sulfur station to deposit sulfur on the carbon nanotubes. For example, molten sulfur can be applied to the CNTs, and sulfur is then driven to within the CNTs. An optional barrier layer can be applied. The sulfur embedded CNT material can be formed on one side or on two sides of the metal foil.

What is claimed is:

1. An electrode for use in an electrochemical cell, comprising
a collector plate;
carbon nanotubes grown on the collector plate, wherein the carbon nanotubes are chemically bonded to the surface of the collector plate.

2. An electrode as in claim 1 wherein the carbon nanotubes are grown on two opposite sides of the collector plate.

3. An electrode as in claim 1 wherein the carbon nanotubes are vertically aligned on the collector plate.

4. A cathode for use in an electrochemical cell, comprising
a collector plate;
carbon nanotubes grown on the collector plate, wherein the carbon nanotubes are chemically bonded to the surface of the collector plate;
elemental sulfur embedded in the carbon nanotubes.

5. A cathode as in claim 4 wherein the carbon nanotubes are grown on two opposite sides of the collector plate.

6. A cathode as in claim 4 wherein the carbon nanotubes are vertically aligned on the collector plate.

7. A cathode as in claim 6 wherein the vertically aligned carbon nanotubes are grown on two opposite sides of the collector plate.

8. A cathode as in claim 4 wherein the collector plate comprises a seed layer for growing the carbon nanotubes.

9. A cathode as in claim 4 wherein the collector plate is flexible and rolled to a reel.

10. An electrochemical cell comprising a cathode as in claim 1.

11. A cathode as in claim 4 further comprising an anode comprising
an anode collector plate;
anode carbon nanotubes grown on the anode collector plate, wherein the anode carbon nanotubes chemically bonded to the surface of the anode collector plate;
active material comprising lithium embedded in the anode carbon nanotubes.

12. A method for making an electrode for use in an electrochemical cell, comprising
providing a collector plate;
growing carbon nanotubes on the collector plate, wherein the carbon nanotubes are chemically bonded to the surface of the collector plate;
depositing molten elemental sulfur on top of the carbon nanotubes, wherein the elemental sulfur is driven to carbon nanotubes toward the collector plate.

13. A method as in claim 12 further comprising
depositing a seed layer on the collector plate to facilitate the growth of carbon nanotubes.

14. A method as in claim 12 further comprising
depositing active material comprising lithium or lithium ion on top of the carbon nanotubes, wherein the active material is driven to carbon nanotubes toward the collector plate.

15. A method as in claim 12 further comprising
depositing a barrier layer on top of the carbon nanotubes after the deposition of sulfur.

16. A method as in claim 12 wherein the carbon nanotubes are grown on two opposite sides of the collector plate.

17. A method as in claim 16 wherein the carbon nanotubes are vertically aligned on the collector plate.

18. A method as in claim 12 wherein the vertically aligned carbon nanotubes are grown on two opposite sides of the collector plate.

19. A method as in claim 12 wherein the carbon nanotubes are grown by PECVD process.

20. A method as in claim 12 wherein the collector plate is flexible and rolled to a reel.
